(19) United States
(12) Patent Application Publication
(10) Pub. No.: US 2018/0374838 A1
(43) Pub. Date: Dec. 27, 2018

(54) SEMICONDUCTOR STRUCTURE

(71) Applicant: MACRONIX INTERNATIONAL CO., LTD., Hsinchu (TW)

(72) Inventors: Wen-Tsung Huang, Changhua County (TW); Ming-Yin Lee, Hsinchu City (TW); Shih-Yu Wang, Taipei City (TW)

(21) Appl. No.: 15/631,141

(22) Filed: Jun. 23, 2017

(51) Int. Cl. H01L 27/02; H01L 29/78; H01L 29/08

(52) U.S. Cl. CPC H01L 27/0248; H01L 29/0847; H01L 29/78

(57) ABSTRACT

A semiconductor structure comprises a transistor. The transistor comprises a semiconductor substrate, a first source/drain side doped region, a second source/drain side doped region and a gate structure. The first source/drain side doped region comprises a lower doped portion having a conductivity type opposing to a conductivity type of the semiconductor substrate. The second source/drain side doped region comprises a first doped portion extended downward from an upper surface of the semiconductor substrate. The second source/drain side doped region has a bottom PN junction with the semiconductor substrate. The lower doped portion has a bottom surface below the bottom PN junction. A dopant concentration of the first doped portion is larger than a dopant concentration of the lower doped portion having the same conductivity type with the first doped portion.

### BACKGROUND

### Technical Field

The disclosure relates to a semiconductor structure, and particularly to a semiconductor structure having a transistor.

### Description of the Related Art

The electrostatic discharge (ESD) is a phenomenon of electrostatic charge transfer between different objects with the accumulation of the electrostatic charges. The ESD occurs for an extremely short period of time, which is only within the level of several nano-seconds (ns). A very high current is generated in the ESD event, and the value of the current is usually several amperes. Consequently, once the ESD event occurs, an IC circuit without using an ESD protection device is usually damaged. As to a design adopting a conventional MOS structure as an ESD element for a contact pad for a LV operation, a long distance of a drain conductive contact to a poly gate (DCGS) of the MOS is enough for providing a sufficient ESD protecting ability. However, the long DCGS will result in an increased parasitical junction capacitance as well as a decreased operating efficiency. On the contrary, the MOS having a short DCGS could not provide a sufficient ESD protecting ability. Moreover, as to a design adopting a conventional MOS structure as an ESD element for a contact pad for a HV operation, the device has a weak ESD protecting ability.

### SUMMARY

The present disclosure relates to a semiconductor structure.

According to an embodiment, a semiconductor structure is disclosed. The semiconductor structure comprises a transistor. The transistor comprises a semiconductor substrate, a first source/drain side doped region, a second source/drain side doped region and a gate structure. The first source/drain side doped region comprises a lower doped portion having a conductivity type opposing to a conductivity type of the semiconductor substrate. The second source/drain side doped region comprises a first doped portion extended downward from an upper surface of the semiconductor substrate. The second source/drain side doped region has a bottom PN junction with the semiconductor substrate. The lower doped portion has a bottom surface below the bottom PN junction. A dopant concentration of the first doped portion is larger than a dopant concentration of the lower doped portion having the same conductivity type with the first doped portion. The gate structure is on the semiconductor substrate between the first source/drain side doped region and the second source/drain side doped region.

According to an another embodiment, a semiconductor structure is disclosed. The semiconductor structure comprises a NMOS transistor. The NMOS transistor comprises a semiconductor substrate, a drain side doped region, a source side doped region and a gate structure. The drain side doped region has a first PN junction with the semiconductor substrate. The drain side doped region comprises a lower doped portion forming a bottom surface of the first PN junction. The source side doped region comprises a first doped portion extended downward from an upper surface of the semiconductor substrate. The source side doped region has a second PN junction with the semiconductor substrate. The bottom surface of the first PN junction is below a bottom surface of the second PN junction. A dopant concentration of the first doped portion is larger than a dopant concentration of the lower doped portion having the same conductivity type with the first doped portion. The gate structure is on the semiconductor substrate between the drain side doped region and the source side doped region. The NMOS transistor is used for a (HVMOS) or for an ESD protection device of the semiconductor structure.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a top view of a MOS transistor according to a first embodiment.

FIG. 2 is a cross-section view of the MOS transistor according to the first embodiment.

FIG. 3 is a cross-section view of the MOS transistor according to the first embodiment.

FIG. 4 illustrates a top view of a MOS transistor according to the first embodiment.

FIG. 5 illustrates a top view of a MOS transistor according to a second embodiment.

FIG. 6 illustrates a top view of a MOS transistor according to the second embodiment.

FIG. 7 is a cross-section view of the MOS transistor according to the second embodiment.

FIG. 8 illustrates a cross-section view of a MOS transistor according to a third embodiment.

FIG. 9 illustrates a top view of a MOS transistor according to the third embodiment.

FIG. 10 illustrates a top view of a MOS transistor according to a fourth embodiment.

FIG. 11 is a cross-section view of the MOS transistor according to the fourth embodiment.

FIG. 12 illustrates a top view of a MOS transistor according to the fourth embodiment.

FIG. 13 illustrates a top view of a MOS transistor according to a fifth embodiment.

FIG. 14 is a cross-section view of the MOS transistor according to the fifth embodiment.

FIG. 15 illustrates a top view of a MOS transistor according to a sixth embodiment.

FIG. 16 is a cross-section view of the MOS transistor according to the sixth embodiment.

FIG. 17 illustrates a top view of a MOS transistor according to a seventh embodiment.

FIG. 18 is a cross-section view of the MOS transistor according to the seventh embodiment.

FIG. 19 illustrates a top view of a MOS transistor according to an eighth embodiment.

FIG. 20 is a cross-section view of the MOS transistor according to the eighth embodiment.

FIG. 21 illustrates a circuit of a semiconductor structure according to the ninth embodiment.

FIG. 22 shows electrical results of semiconductor structure of a comparative example and embodiments.

FIG. 23 illustrates a top view of a resistor according to the tenth embodiment.

FIG. 24 is a cross-section view of the resistor according to the tenth embodiment.

FIG. 25 illustrates a top view of a resistor according to the eleventh embodiment.

FIG. 26 is a cross-section view of the resistor according to the eleventh embodiment.

FIG. 27 is a cross-section view of the resistor according to the eleventh embodiment.

FIG. 28 illustrates a top view of a resistor according to the twelfth embodiment.

FIG. 29 shows electrical results of semiconductor structure of a comparative example and embodiments.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

### First Embodiment

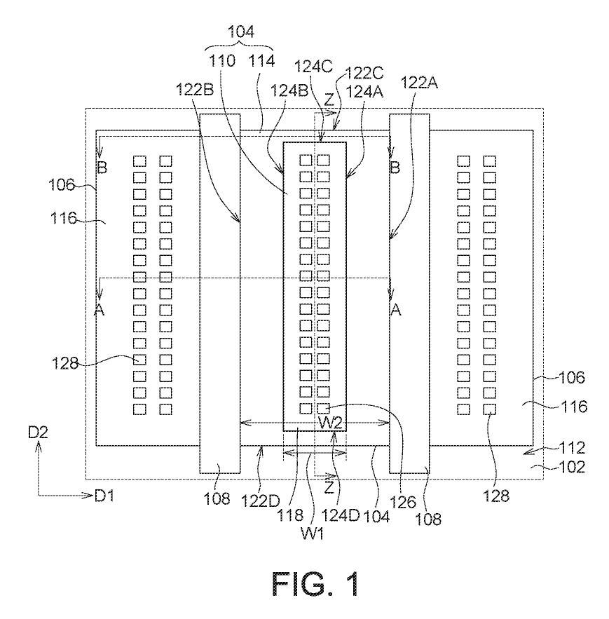

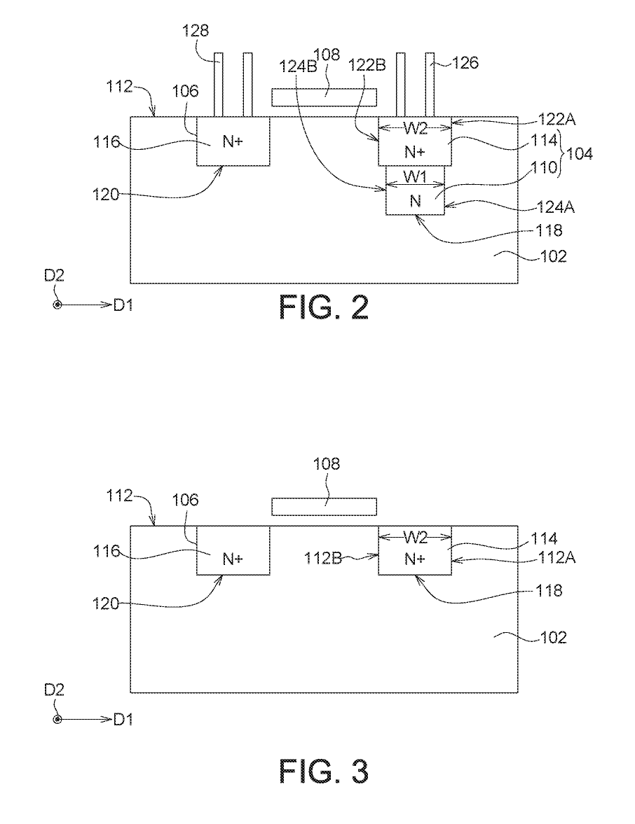

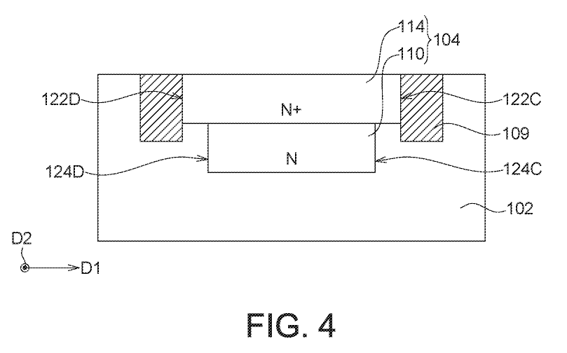

Referring to FIG. 1 to FIG. 4, a NMOS transistor according to the first embodiment is shown. FIG. 1 shows a top view of the MOS transistor. FIG. 2 is a cross-section view drawn along a AA line in FIG. 1. FIG. 3 is a cross-section view drawn along a BB line in FIG. 1. FIG. 4 is a cross-section view drawn along a ZZ line in FIG. 1. The MOS transistor comprises a N-type first source/drain side doped region 104 and a N-type second source/drain side doped region 106 formed in a P-type semiconductor substrate 102, and a gate structure 108 on the semiconductor substrate 102.

The first source/drain side doped region 104 comprises a lower doped portion 110 and an upper doped portion 114 on the lower doped portion 110 formed by doping the semiconductor substrate 102 from an upper surface 112 of the semiconductor substrate 102. The second source/drain side doped region 106 comprises a first doped portion 116 formed by doping the semiconductor substrate 102 from the upper surface 112 of the semiconductor substrate 102. In embodiments, the lower doped portion 110 has a (net) N-type dopant concentration smaller than a (net) N-type dopant concentration of the upper doped portion 114, and smaller than a (net) N-type dopant concentration of the first doped portion 116. In figures of the disclosure, a shown symbol of “N” may indicate a region having a (net) N-type dopant concentration smaller than a region marked with a symbol of “N+”. In an embodiment, for example, the upper doped portion 114 of the first source/drain side doped region 104 is functioned as a heavily doped drain region of the MOS transistor, and the second source/drain side doped region 106 of the first doped portion 116 is functioned as a heavily doped source region of the MOS transistor. In embodiments, the lower doped portion 110 having a smaller dopant concentration than the first doped portion 116 is doped in the semiconductor substrate 102 with a bigger depth than the first doped portion 116, and thus the lower doped portion 110 has a bottom surface 118 (or a bottom PN junction formed with the semiconductor substrate 102) is below a bottom PN junction 120 of the first doped portion 116 formed with the semiconductor substrate 102.

For example, the upper doped portion 114 and the first doped portion 116 may be heavily doped regions formed simultaneously with an implantation process. The (net) N-type dopant concentration of the upper doped portion 114 may be equal to the (net) N-type dopant concentration of the first doped portion 116. In an embodiment, an implantation process for forming the lower doped portion 110 may also dope dopant into a region of the upper doped portion 114, and thus the (net) N-type dopant concentration of the upper doped portion 114 may be larger than the (net) N-type dopant concentration of the first doped portion 116. In embodiments, for example, a profile of the upper doped portion 114 may be defined by using the gate structure 108 and an isolation structure 109. The isolation structure is not limited to a shallow trench structure (STI), and may use other kinds of isolation elements such as FOX structures, etc.

In the embodiment, opposing sidewall surfaces 122A and 122B of the upper doped portion 114 are disposed outside of opposing sidewall surfaces 124A and 124B of the lower doped portion 110 in a source to drain direction D1. In addition, the lower doped portion 110 has a width W1 smaller than a width W2 of the upper doped portion 114. Moreover, opposing sidewall surfaces 122C and 122D of the upper doped portion 114 are disposed outside of opposing sidewall surfaces 124C and 124D of the lower doped portion 110 in a direction D2 crisscrossing the source to drain direction D1, for example a direction substantially perpendicular to an extending direction of length of the gate structure 108/a source/a drain. A conductive contact 126 and a conductive contact 128 may be electrically connected to the upper doped portion 114 on the lower doped portion and the first doped portion 116, respectively. As shown in the top view of FIG. 1, the conductive contact 126 is arranged in the profile area of the lower doped portion 110. The gate structure 108 is extended beyond the sidewall surface 122C and the sidewall surface 122C of the upper doped portion 114 in the direction D2.

### Second Embodiment

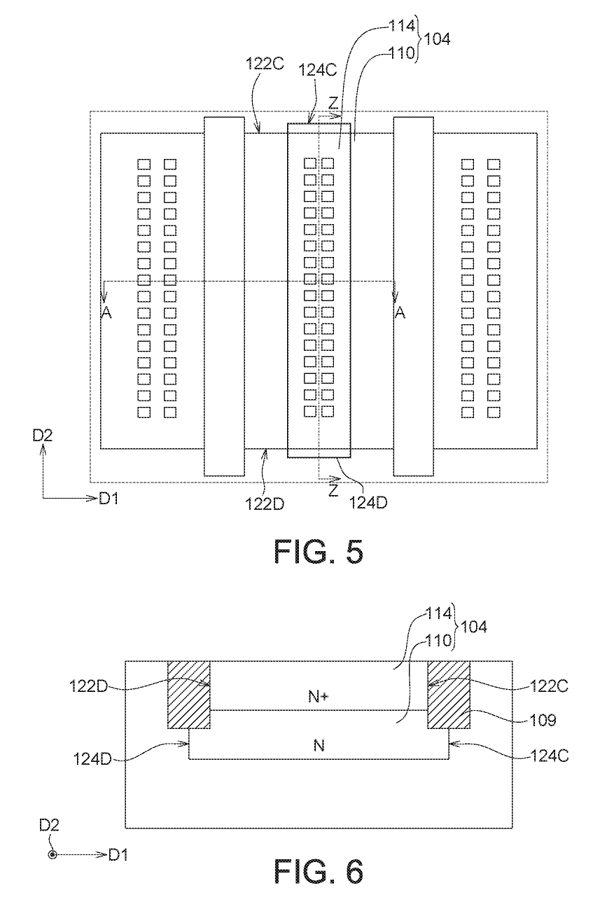

Please refer to FIG. 5 and FIG. 6. FIG. 5 illustrates a top view of the MOS transistor according to the second embodiment. FIG. 6 is a cross-section view drawn along the ZZ line in FIG. 5. The second embodiment is different from the first embodiment in that lower doped portion 110 of the first source/drain side doped region 104 is extended beyond the upper doped portion 114 in the direction D2. In other words, the opposing sidewall surfaces 124C and 124D of the lower doped portion 110 are disposed outside of the opposing sidewall surfaces 122C and 122D of the upper doped portion. A cross-section view of the MOS transistor across the upper doped portion 114 (for example a cross-section view along the AA line in FIG. 5) may be similar to the cross-section view of FIG. 2.

### Third Embodiment

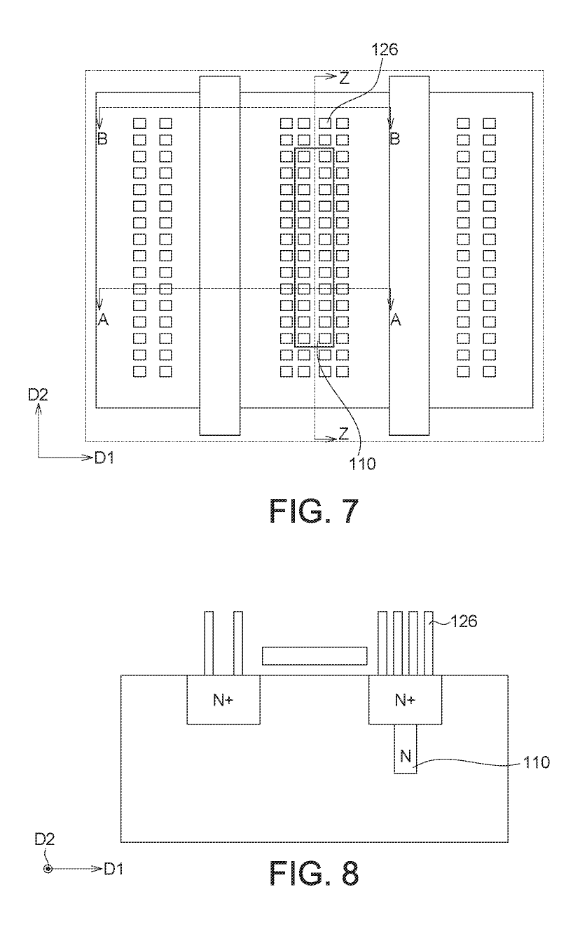

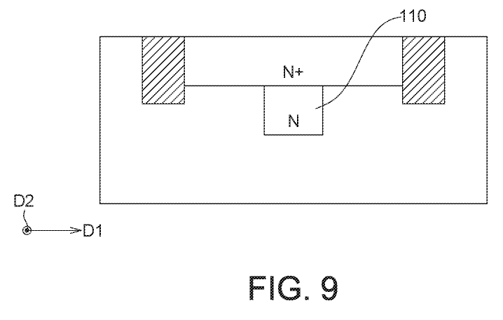

FIG. 7 to FIG. 9 show the MOS transistor according to the third embodiment. FIG. 7 is a top view of the MOS transistor. FIG. 8 is a cross-section view drawn along the AA line in FIG. 7. FIG. 9 is a cross-section view drawn along the ZZ line in FIG. 7. The third embodiment is different form the first embodiment in that the lower doped portion 110 of the third embodiment has a smaller size than the lower doped portion 110 of the first embodiment. In addition, as shown in the top view of FIG. 7, the conductive contact 126 may be arranged not only in the profile region of the lower doped portion 110, but also in a region outside of the profile region of the lower doped portion 110. For example, a cross-section view of the MOS transistor along the BB line in FIG. 7 is similar to the cross-section view of FIG. 3.

### Fourth Embodiment

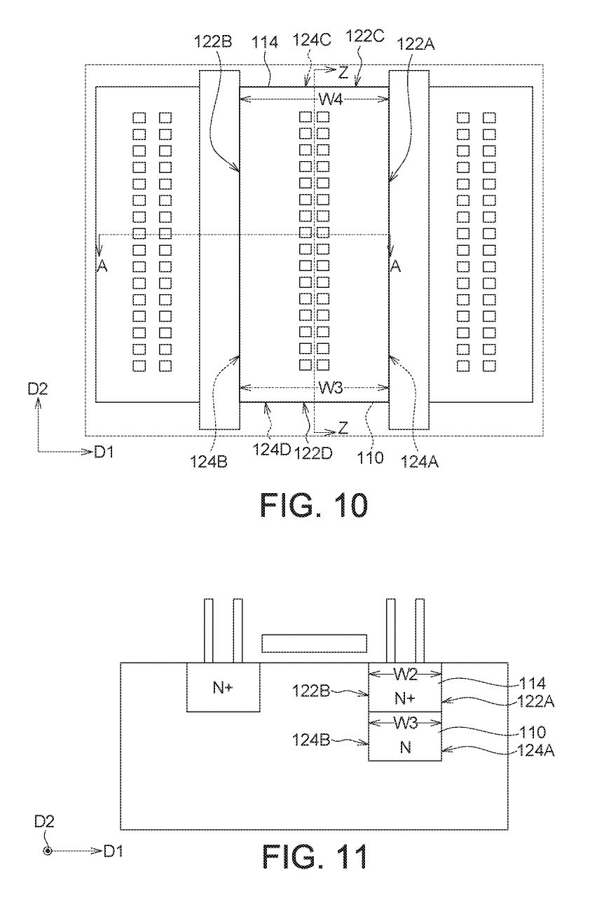

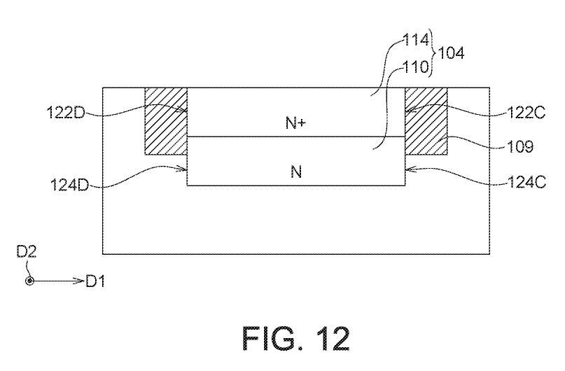

FIG. 10 to FIG. 12 show the MOS transistor according to the fourth embodiment. FIG. 10 is a top view of the MOS transistor. FIG. 11 is a cross-section view drawn along the AA line in FIG. 10. FIG. 12 is a cross-section view drawn along the ZZ line in FIG. 10. The fourth embodiment is different form the first embodiment in that lateral areas (i.e. doped areas viewed from the top view) of the lower doped portion 110 and the upper doped portion 114 are substantially the same. For example, the lower doped portion 110 has a width W3 substantially equal to the width W2 of the upper doped portion 114. The sidewall surfaces 124A, 124B, 124C and 124D of the lower doped portion 110 may respectively align with the sidewall surfaces 122A, 122B, 122C and 122D of the upper doped portion 114 substantially.

### Fifth Embodiment

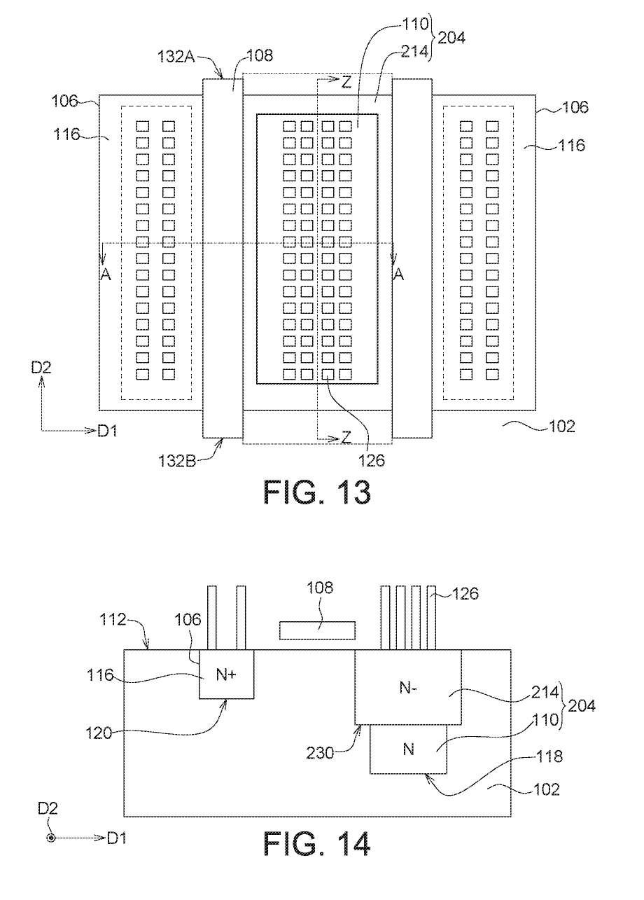

FIG. 13 and FIG. 14 show the MOS transistor according to the fifth embodiment. FIG. 13 is a top view of the MOS transistor. FIG. 14 is a cross-section view drawn along the AA line in FIG. 13. A difference between the fifth embodiment and the first embodiment is illustrated as the following. The first source/drain side doped region 204 comprises the lower doped portion 110 and an upper doped portion 214 on the lower doped portion 110 formed by doping the semiconductor substrate 102 from the upper surface 112 of the semiconductor substrate 102. In embodiments, the (net) N-type dopant concentration of the upper doped portion 214 is smaller than the (net) N-type dopant concentration of the first doped portion 116.

In an embodiment, for example, the (net) N-type dopant concentration of the lower doped portion 110 having the bottom surface 118 below the bottom PN junction 120 is bigger than a (net) N-type dopant concentration of the upper doped portion 214, and smaller than the (net) N-type dopant concentration of the first doped portion 116. In figures of the disclosure, the symbol of “N” may indicate a region having a (net) N-type dopant concentration smaller than a region marked with a symbol of “N+” and bigger than a region marked with a symbol of “N−”. However, the present disclosure is not limited thereto. In other embodiments, the lower doped portion 110 may be replaced by a lower doped portion having a (net) N-type dopant concentration identical to or lower than the (net) N-type dopant concentration of the upper doped portion 214.

In an embodiment, for example, the upper doped portion 214 of the first source/drain side doped region 204 is electrically connected to the drain conductive contact 126 of the MOS transistor, and the first doped portion 116 of the second source/drain side doped region 106 is functioned as the heavily doped source region of the MOS transistor. The upper doped portion 214 and the first doped portion 116 are both extended downward from the upper surface 112 of the semiconductor substrate 102. In an embodiment, as shown in FIG. 14, the upper doped portion 214 has a bottom surface 230 disposed below the first doped portion 116. However, the present disclosure is not limited thereto. In other embodiments, the bottom surface 230 of the upper doped portion 214 may be above or in the same level with the bottom surface of the first doped portion 116.

### Sixth Embodiment

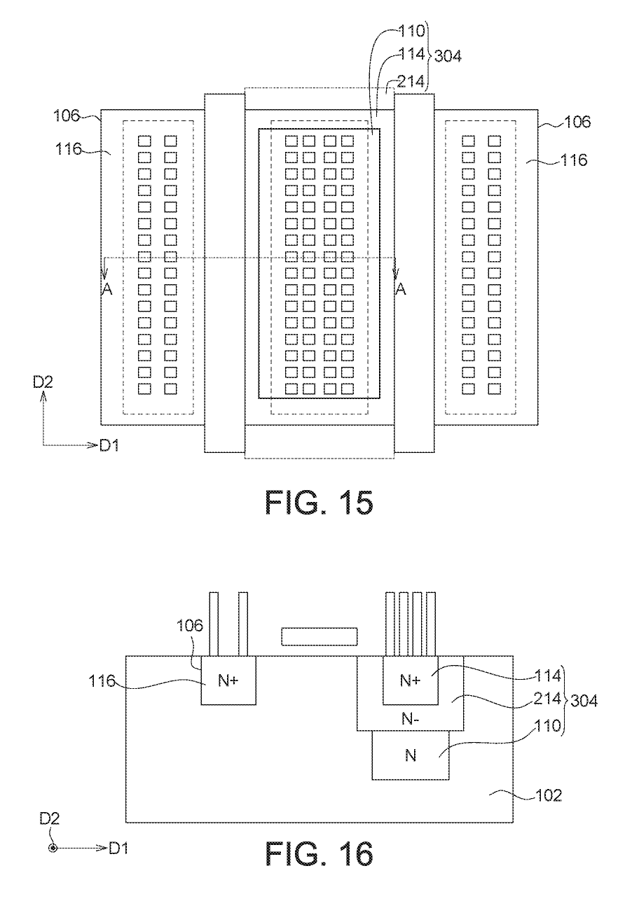

FIG. 15 and FIG. 16 show the MOS transistor according to the sixth embodiment. FIG. 15 is a top view of the MOS transistor. FIG. 16 is a cross-section view drawn along the AA line in FIG. 15. The sixth embodiment is different from the fifth embodiment in that the first source/drain side doped region 304 further comprises the upper doped portion 114 formed in the upper doped portion 214. Characteristics of the upper doped portion 114 may be similar to those as illustrated in the first embodiment. Therefore, for example, the lower doped portion 110 of the sixth embodiment may have the dopant concentration (marked with the symbol of “N”) bigger than the dopant concentration (marked with the symbol of “N−”) of the upper doped portion 214, and smaller than the dopant concentrations (marked with the symbol of “N+”) of the first doped portion 116 and the upper doped portion 114. The other characteristics resulted from the upper doped portion 114 included by the semiconductor structure of the sixth embodiment compared to the fifth embodiment may be deduced by analogy.

### Seven Embodiment

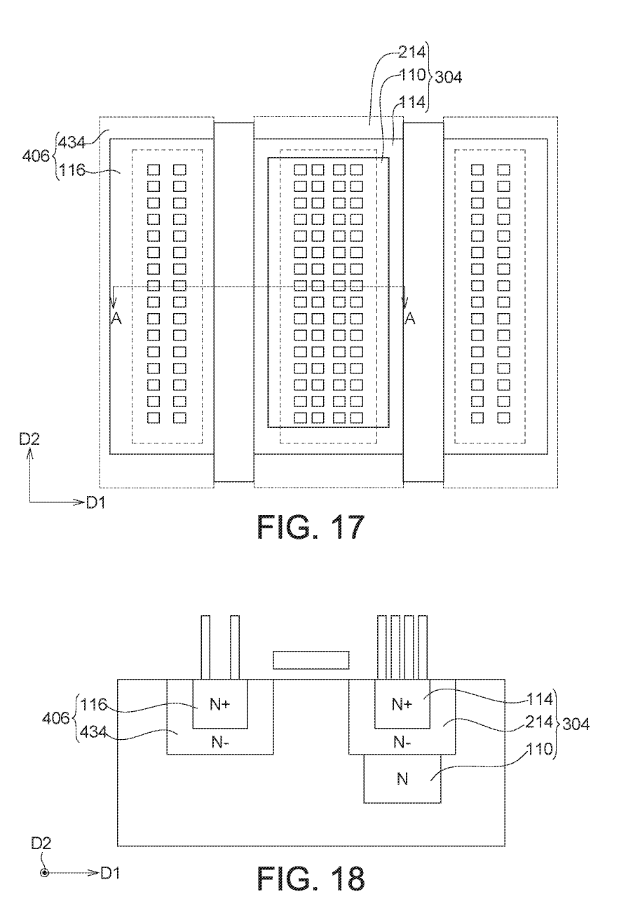

FIG. 17 and FIG. 18 show the MOS transistor according to the seven embodiment. FIG. 17 is a top view of the MOS transistor. FIG. 18 is a cross-section view drawn along the AA line in FIG. 17. The seven embodiment is different from the sixth embodiment in that the second source/drain side doped region 406 further comprises a second doped portion 434 with the first doped portion 116 formed therein. the lower doped portion 110 of the seven embodiment may have the dopant concentration (marked with the symbol of “N”) bigger than the dopant concentrations (marked with the symbol of “N−”) of the second doped portion 434 and the upper doped portion 214, and smaller than the dopant concentrations (marked with the symbol of “N+”) of the first doped portion 116 and the upper doped portion 114. In an embodiment, for example, the second doped portion 434 and the upper doped portion 214 may be formed simultaneously with an implantation process, and thus have the same depth.

### Eighth Embodiment

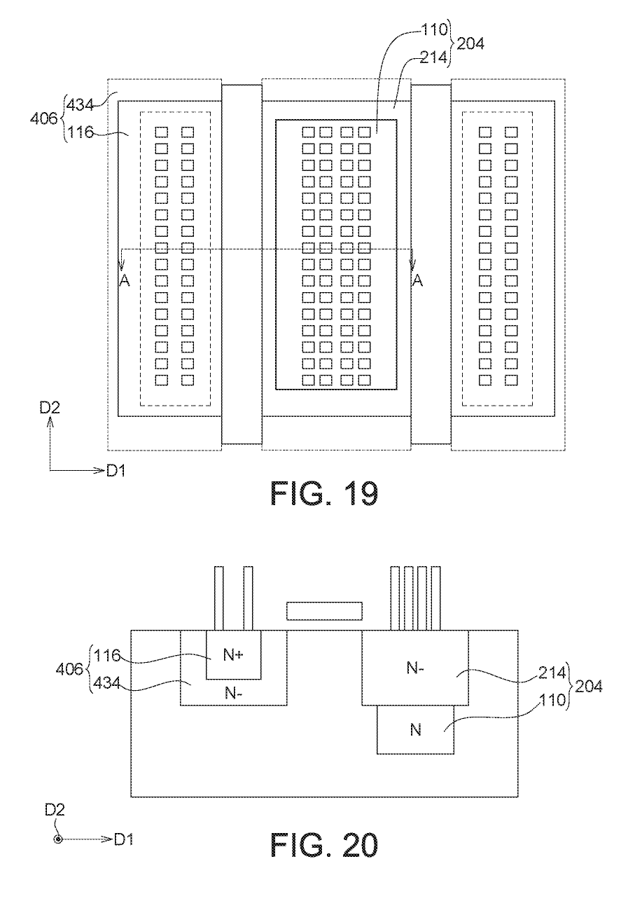

FIG. 19 and FIG. 20 show the MOS transistor according to the eighth embodiment. FIG. 19 is a top view of the MOS transistor. FIG. 20 is a cross-section view drawn along the AA line in FIG. 19. The eighth embodiment is different from the fifth embodiment in that the second source/drain side doped region 406 further comprises the second doped portion 434 with the first doped portion 116 formed therein. Characteristics of the second doped portion 434 of the eighth embodiment are similar to those of the second doped portion 434 as illustrated in seventh embodiment. Therefore, for example, the lower doped portion 110 of the eighth embodiment may have the dopant concentration (marked with the symbol of “N”) bigger than the dopant concentrations (marked with the symbol of “N−”) of the upper doped portion 214 and the second doped portion 434, and smaller than the dopant concentration (marked with the symbol of “N+”) of the first doped portion 116. The other characteristics resulted from the second doped portion 434 included by the semiconductor structure of the eighth embodiment compared to the fifth embodiment may be deduced by analogy.

The concepts for the MOS transistor of the embodiments may be applied to other kinds of MOS transistors, for example a PMOS transistor.

The MOS transistor according to embodiments may be applied for improving properties of the semiconductor structure device. For example, the MOS transistor may be applied in an ESD protection device so as to have a decreased parasitical junction capacitance while maintaining an expected ESD protecting characteristic as operated under a low voltage. Alternatively, the MOS transistor may be used as a HVNMOS for a better ESD capability. Some embodiments are illustrated as the following.

### Ninth Embodiment

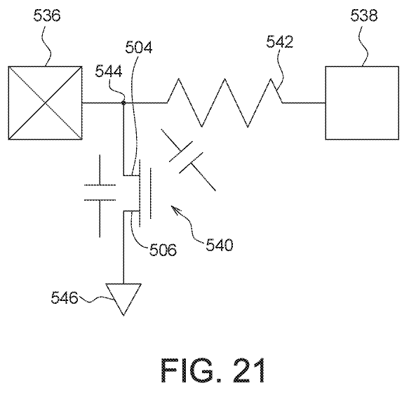

FIG. 21 illustrates a circuit of the semiconductor structure, comprising a ESD protection device electrically connected between an (external) contact pad 536 and an internal circuit 538 to be protected. The ESD protection device comprises the MOS transistor 540 and a resistor 542. The resistor 542 is electrically connected between the contact pad 536 and the internal circuit 538. The MOS transistor 540 has the first source/drain side doped region 504 electrically connected to a node 544 between the resistor 542 and the contact pad 536. The MOS transistor 540 has the second source/drain side doped region 506 electrically connected to a ground 546.

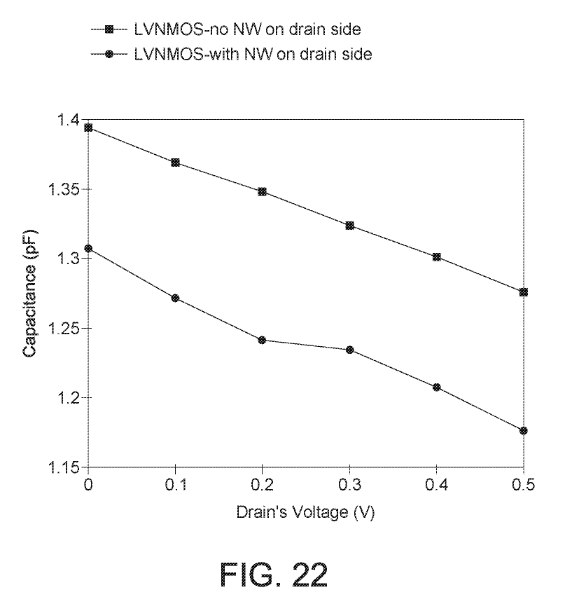

In embodiments, for example, the MOS transistor 540 of the ESD protection device may use the MOS transistor of the first embodiment to the fourth embodiment. Referring to test results shown in FIG. 22, compared to a MOS transistor of a comparative example without a lower doped portion in a first source/drain side doped region, the MOS transistors having the lower doped portion 110 included in the first source/drain side doped region according to the embodiments can have smaller (parasitical junction) capacitances under the same drain voltages while having the same ESD protecting characteristic as that of the comparative example since the lower doped portion 110 having a lower dopant concentration than the upper doped portion 114 could result in a lager depletion width. The characteristics of the embodiments can result in a faster operating efficiency of the contact pad than the comparative example.

In other embodiments, the operating efficiency of the ESD protection device may be improved while maintaining the expected ESD protecting ability through other designs to the contact pad. Structures for the resistor 542 according to embodiments are illustrated as the following.

### Tenth Embodiment

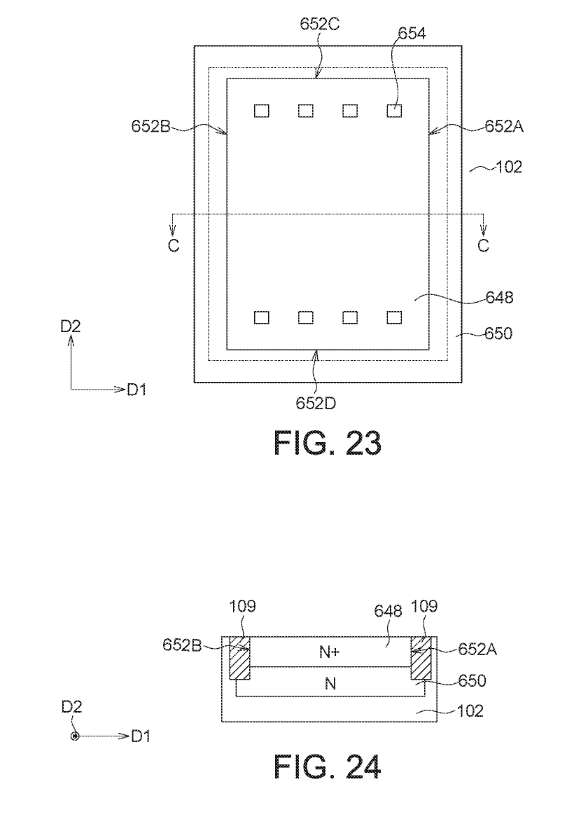

FIG. 23 and FIG. 24 show the resistor of the tenth embodiment. FIG. 23 is a top view of the resistor. FIG. 24 is a cross-section view drawn along a CC line in FIG. 23. The resistor comprises the P-type semiconductor substrate 102, a N-type first resistor doped region 648 and a N-type second resistor doped region 650. The second resistor doped region 650 is formed in the semiconductor substrate 102. The first resistor doped region 648 is formed in the second resistor doped region 650. In embodiments, for example, the first resistor doped region 648 may have a (net) N-type dopant concentration (marked with the symbol of “N+”) bigger than a (net) N-type dopant concentration (marked with the symbol of “N”) of the second resistor doped region 650. In the embodiment, the second resistor doped region 650 surrounds all sidewall surfaces 652A-652D of the first resistor doped region 648. A conductive contact 654 is electrically connected to the first resistor doped region 648. For example, the conductive contact 654 may be electrically connected to a drain side conductive contact of the MOS transistor (for example the conductive contact 126 illustrated in the first embodiment). In embodiments, for example, the profile of the upper doped portion 114 may be defined by using the isolation structure 109. The isolation structure is not limited to a shallow trench structure (STI), and may use other kinds of isolation elements such as FOX structures, etc.

### Eleventh Embodiment

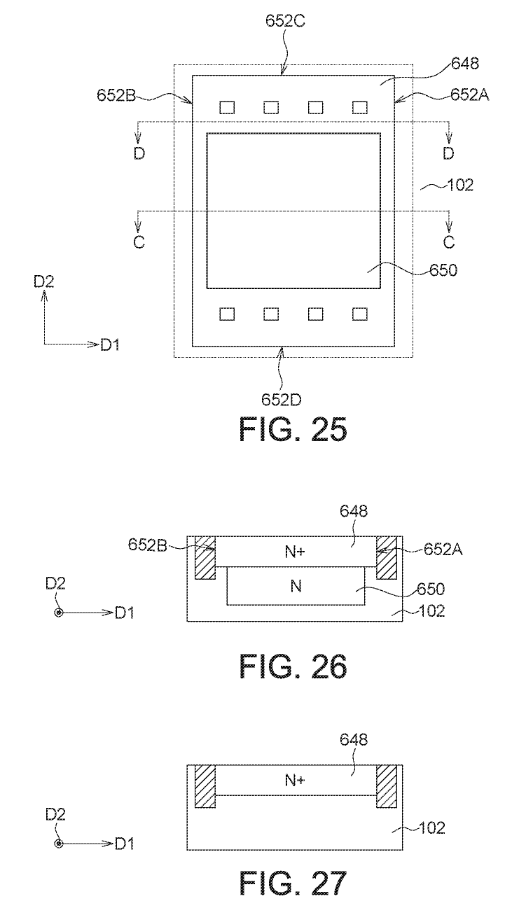

FIG. 25 to FIG. 27 show the resistor of the eleventh embodiment. FIG. 25 is a top view of the resistor. FIG. 26 is a cross-section view drawn along the CC line in FIG. 25. FIG. 27 is a cross-section view drawn along a DD line in FIG. 25. The eleventh embodiment is different from the tenth embodiment is that the second resistor doped region 650 is extended not beyond all of the sidewall surfaces 652A-652D of the first resistor doped region 648 in a lateral direction.

### Twelfth Embodiment

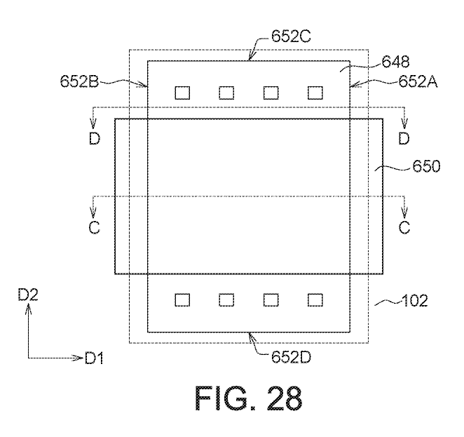

FIG. 28 illustrates a top view of the resistor of the twelfth embodiment. In the twelfth embodiment, a cross-section view of the resistor along the CC line may be similar to FIG. 24, and a cross-section view of the resistor along the DD line may be similar to FIG. 27. The twelfth embodiment is different from the tenth embodiment in that the second resistor doped region 650 is extended beyond opposing sidewall surfaces 652A and 652B of the first resistor doped region 648, and not beyond opposing sidewall surfaces 652C and 652D of the first resistor doped region 648 in a lateral direction.

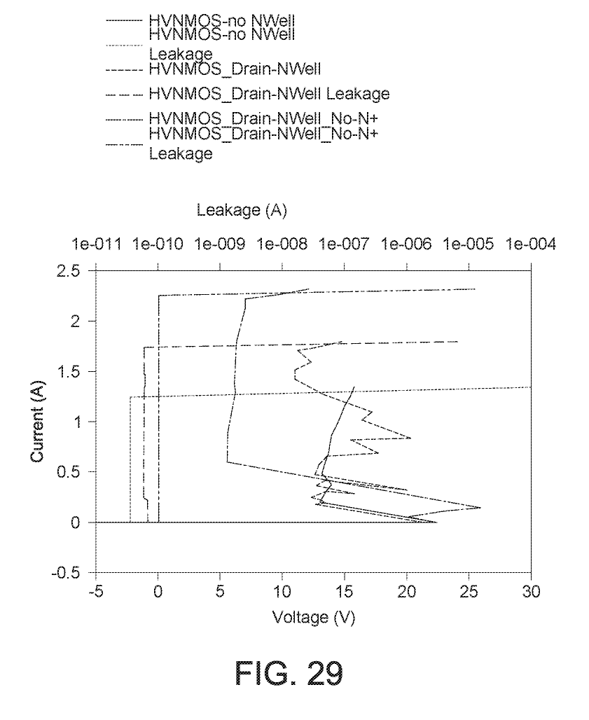

In some embodiments, the MOS transistors of the fifth embodiment to the eighth embodiment may be functioned as a HVMOS MOS transistor. Referring to test results shown in FIG. 29, compared to a MOS transistor of a comparative example without a lower doped portion, the MOS transistors having the lower doped portion 110 under a drain of the first source/drain side doped region according to the embodiments can have better ESD capability due to an additional current path provided from the lower doped portion 110 that could avoid an early breakdown between the (for example N type) drain and an adjacent (for example P type) well having opposing conductivity types. In addition, in some embodiments, for example referring to FIG. 13 and FIG. 14 for illustrating the fifth embodiment or FIG. 19 and FIG. 20 for illustrating the eighth embodiment, in which the upper doped portion has only the upper doped portion 214 having the N-type dopant concentration smaller than that of the first doped portion 116, and the conductive contact 126 is electrically connected with the upper doped portion 214, the upper doped portion 214 can sustain a lower thermal stress, and thus the device can have a better ESD protecting ability.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A semiconductor structure, comprising a transistor, wherein the transistor comprises:
a semiconductor substrate;
a first source/drain side doped region comprising a lower doped portion having a conductivity type opposing to a conductivity type of the semiconductor substrate;
a second source/drain side doped region comprising a first doped portion extended downward from an upper surface of the semiconductor substrate and having a bottom PN junction with the semiconductor substrate, wherein the lower doped portion has a bottom surface below the bottom PN junction, a dopant concentration of the first doped portion is larger than a dopant concentration of the lower doped portion having the same conductivity type with the first doped portion; and
a gate structure on the semiconductor substrate between the first source/drain side doped region and the second source/drain side doped region.

2. The semiconductor structure according to claim 1, wherein the first source/drain side doped region further comprises an upper doped portion on the lower doped portion, the lower doped portion is extended not beyond opposing sidewall surfaces of the upper doped portion in a source to drain direction.

3. The semiconductor structure according to claim 2, wherein the lower doped portion has a width equal to or smaller than a width of the upper doped portion in the source to drain direction.

4. The semiconductor structure according to claim 1, wherein the first source/drain side doped region further comprises an upper doped portion on the lower doped portion, the upper doped portion has a dopant concentration equal to the dopant concentration of the first doped portion having the same conductivity type and the same depth with the upper doped portion.

5. The semiconductor structure according to claim 1, wherein the first source/drain side doped region further comprises an upper doped portion on the lower doped portion, the upper doped portion has a dopant concentration larger than or equal to a dopant concentration of the first doped portion having the same conductivity type with the upper doped portion.

6. The semiconductor structure according to claim 1, wherein the first source/drain side doped region further comprises an upper doped portion on the lower doped portion, the upper doped portion is extended downward from the upper surface of the semiconductor substrate.

7. The semiconductor structure according to claim 1, wherein the transistor is functioned as a NMOS for an ESD protection device.

8. The semiconductor structure according to claim 1, wherein there is no PN junction between the lower doped portion and a drain doped region of the transistor.

9. The semiconductor structure according to claim 1, comprising an ESD protection device, wherein the ESD protection device comprises:
the transistor; and
a resistor electrically connected to the first source/drain side doped region.

10. The semiconductor structure according to claim 9, further comprising a contact pad electrically connected to a node between the resistor and the first source/drain side doped region, wherein the second source/drain side doped region electrically connected to a ground.

11. The semiconductor structure according to claim 9, wherein the resistor comprises:
a first resistor doped region; and
a second resistor doped region adjoined with a lower surface of the first resistor doped region and having a PN junction with the semiconductor substrate, wherein the first resistor doped region has a dopant concentration larger than a dopant concentration of the second resistor doped region having the same conductivity type with the first resistor doped region.

12. The semiconductor structure according to claim 9, wherein the second resistor doped region surrounds all sidewall surfaces of the first resistor doped region.

13. The semiconductor structure according to claim 9, wherein the second resistor doped region is extended in a lateral direction not beyond all sidewall surfaces of the first resistor doped region.

14. The semiconductor structure according to claim 9, wherein the second resistor doped region is extended in a lateral direction not beyond a couple of opposing sidewall surfaces of the first resistor doped region, but extended beyond an another couple of opposing sidewall surfaces of the first resistor doped region.

15. The semiconductor structure according to claim 1, wherein the first source/drain side doped region further comprises an upper doped portion adjoined on the lower doped portion, the upper doped portion has a dopant concentration smaller than a dopant concentration of the dopant concentration of the first doped portion having the same conductivity type with the upper doped portion.

16. The semiconductor structure according to claim 15, further comprising a conductive contact electrically connected with the upper doped portion.

17. The semiconductor structure according to claim 15, wherein the first source/drain side doped region further comprises an another upper doped portion formed in the upper doped portion, the another upper doped portion has a dopant concentration larger than a dopant concentration of the lower doped portion and larger than a dopant concentration of the upper doped portion having the same conductivity type with the another upper doped portion.

18. The semiconductor structure according to claim 15, wherein the second source/drain side doped region further comprises a second doped portion, the first doped portion is formed in the second doped portion, the second doped portion has a dopant concentration smaller than a dopant concentration of the first doped portion having the same conductivity type with the second doped portion.

19. The semiconductor structure according to claim 15, wherein the lower doped portion is extended in a lateral direction not beyond all sidewall surfaces of the upper doped portion.

20. A semiconductor structure, comprising a NMOS transistor, wherein the NMOS transistor comprises:
a semiconductor substrate;
a drain side doped region having a first PN junction with the semiconductor substrate and comprising a lower doped portion forming a bottom surface of the first PN junction;
a source side doped region comprising a first doped portion extended downward from an upper surface of the semiconductor substrate and having a second PN junction with the semiconductor substrate, wherein the bottom surface of the first PN junction is below a bottom surface of the second PN junction, a dopant concentration of the first doped portion is larger than a dopant concentration of the lower doped portion having the same conductivity type with the first doped portion; and
a gate structure on the semiconductor substrate between the drain side doped region and the source side doped region, wherein the NMOS transistor is used for a (HVMOS) or for an ESD protection device of the semiconductor structure.
